(19) United States
(12) Patent Application Publication
(10) Pub. No.: US 2010/0066442 A1
(43) Pub. Date: Mar. 18, 2010

(54) Method and Apparatus for Tunable Current-Mode Filtering

(76) Inventor: Fenghao Mu, Hjarup (SE)

Correspondence Address: COATS & BENNETT, PLLC, 1400 Crescent Green, Suite 300, Cary, NC, 27518, US

(21) Appl. No.: 12/210,483

(22) Filed: Sep. 15, 2008

(51) Int. Cl. H03K 5/00

(52) U.S. Cl. 327/553

(57) ABSTRACT

According to the teachings presented herein, a tunable current-mode filter is implemented using two or more tunable filter stages in cascade connection. For example, a number of tunable filter stages corresponding to a desired filter order are included in the filter in cascade connection. Use of the current-mode filter simplifies circuit design, particularly in communication transmitter applications, and avoids current-to-voltage conversions needed when voltage-mode filters are used in current-mode signal processing chains. A method and circuit to tune and calibrate the frequency response of the filter are disclosed as well.

### TECHNICAL FIELD

The present invention generally relates to filtering, and particularly relates to filtering based on tunable current-mode filters and related methods, such as current-mode cascade low-pass filters (CMLPFs) tunable for bandwidth calibration.

### BACKGROUND

Transmit signal generation in contemporary communication devices typically involves generating a baseband signal in the digital domain, and subsequently converting that digital baseband signal into an analog signal that is used to modulate a carrier frequency signal, to thereby obtain a modulated transmit signal at the desired transmit frequency. Typifying this approach, a baseband digital signal processor generates the digital baseband signal, and a digital-to-analog converter (DAC) converts that signal into the analog domain. Current-mode DACs find advantageous use in such applications, because of their good linearity as compared to many types of voltage-mode DACs. (As is well known, current-mode DACs translate input digital codewords into output currents of corresponding magnitudes.)

All practical DACs, whether voltage- or current-mode, introduce some amount of conversion noise and/or distortion, collectively referred to herein as “reconstruction noise.”Reconstruction noise is particularly problematic in transmit signal chains included within communication transceivers, at least where the noise spectrum extends into receive frequencies. In such cases, receiver-band noise in the transmit signal chain bleeds through local transmit/receive filtering structures, e.g., antenna duplexers, etc., and can severely impair receiver sensitivity.

It is known therefore to use post-DAC filtering in the transmit signal chain. Such filters are typically implemented as voltage-mode low pass filters (LPFs), given the relative ease of implementing feedback-based LPFs with the requisite suppression performance in the voltage-mode domain, as compared to implementing them in the current-mode domain. Notably, the out-of-band suppression performance must be quite good, given the relatively high power of the outgoing transmit signal as compared to the incoming received signals. Of course, if a current-mode DAC provides the baseband analog transmit signal being filtered, current-to-voltage conversion is used at the filter input.

The conversion to voltage-mode, particularly with the use of active circuit devices, compromises at least to some extent the good linearity of the current-mode DAC, and introduces further complications for downstream processing. For example, current-mode mixers for transmit signal modulation are known to offer linearity advantages as compared to their voltage-mode counterparts. If voltage-mode LPFs are used for suppression of reconstruction noise in the transmit signal chain, taking advantage of the performance benefits offered by current-mode mixers requires conversion back to the current-mode domain. The back-and-forth conversion between current-mode and voltage-mode domains adds expense and circuit complexity, and increases the challenges associated with obtaining desired performance.

Beyond the normal concerns of whether such challenges can be met over the normal range of circuit parameter variations inherent in integrated circuit manufacturing, the need for frequency “tunability” in such circuits further complicates their design. For example, in Long Term Evolution (LTE), as being developed by the Third Generation Partnership Project (3GPP), transmit signal bandwidth allocations change with changing data rate needs, etc. Thus, the various circuits comprising the transit signal chain must meet relevant performance requirements for varying signal bandwidths and/or center frequencies.

### SUMMARY

According to the teachings presented herein, a tunable current-mode filter is implemented using at least two cascading tunable filter stages. For example, a plurality of tunable filter stages corresponding to a desired filter order is included in the filter in cascade connection. Use of the current-mode filter simplifies circuit design, particularly in communication transmitter applications, and avoids current-to-voltage conversions needed when voltage-mode filters are used in current-mode signal processing chains.

In one embodiment, a tunable current-mode filter as taught herein comprises a filter input for receiving an input current signal and a corresponding filter output for providing a filtered output current signal, and at least two cascading tunable filter stage interposed between the filter input and the filter output for filtering the input current signal to thereby obtain the filtered output current signal according to a tunable frequency response. Each tunable filter stage comprises a current mirror circuit having first and second branches configured to generate a stage output current by mirroring a stage input current, and two passive networks, one coupled to an output of the first branch and the other one coupled to an output of the second branch of the current mirror circuit. Each passive network includes a tunable element operative to adjust a frequency response of the tunable filter stage responsive to a control signal, and thereby adjust an overall frequency response of the tunable current-mode filter. Correspondingly, the filter includes a control input configured to receive the control signal, such that changing a value of the control signal changes the overall frequency response of the tunable current-mode filter.

In another embodiment, a wireless communication transmitter comprises a current-mode mixer configured to generate a transmit signal by modulating a carrier frequency signal according to a filtered current-mode information signal, and a tunable current-mode filter configured to generate the filtered current-mode information signal by filtering a current-mode information signal. As explained above, the overall frequency response of the tunable current-mode filter is tunable responsive to a control signal. The transmitter further includes a current-mode digital-to-analog converter (DAC) configured to generate the current-mode information signal from a digital baseband information signal, and a control circuit configured to adjust the control signal according to a desired frequency response for the tunable current-mode filter.

In yet another embodiment, a method of adjusting frequency response in a signal processing chain is provided. The signal processing chain includes a tunable current-mode filter having an overall frequency response adjustable as a function of a control signal applied to the tunable current-mode filter, where the filter includes two or more cascading tunable filter stages, each comprising a current mirror circuit having first and second branches, and two passive networks, one coupled to an output of the first branch and the other one coupled to an output of the second branch of the current mirror circuit. Each passive network including a tunable element responsive to the control signal. In this context, the method comprises detecting an overall frequency response of the tunable current-mode filter, and adjusting the control signal as needed according to a desired overall frequency response. Here, detecting the overall frequency response of the tunable current-mode filter comprises directly or indirectly detecting an overall delay time of the tunable current-mode filter.

However, the present invention is not limited to the above summary of features and advantages. Indeed, those skilled in the art will recognize additional features and advantages upon reading the following detailed description, and upon viewing the accompanying drawings.

### BRIEF DESCRIPTION OF THE DRAWINGS

FIG. 1 is block diagram of one embodiment of a tunable current-mode filter as taught herein.

FIG. 2 is a block diagram of one embodiment of a tunable filter stage (TFS), for use in a tunable current-mode filter.

FIGS. 3-5 are block diagrams of a tunable current-mode filter, shown including or in association with various embodiments of a calibration circuit for detecting an overall frequency of the filter and correspondingly adjusting the response.

FIG. 6 is a block diagram for one embodiment of a wireless communication device that includes a tunable current-mode filter within its signal processing chain.

FIG. 7 is a logic flow diagram of one embodiment of a method for detecting overall frequency response of a tunable current-mode filter and correspondingly adjusting it.

FIGS. 8-10 are schematics of one embodiment of a TFS for use in building a tunable current-mode filter, and corresponding passive networks with one or more tunable elements.

FIGS. 11-13 are schematics illustrating another embodiment of the TFS and its corresponding passive networks.

FIG. 14 is a schematic of another embodiment of a TFS that includes one or more DC offset reduction transistors.

FIG. 15 is a schematic of another embodiment of a TFS that includes one or more DC offset reduction transistors.

FIG. 16 is a schematic of one embodiment of a DC offset detection circuit that is configured to generate offset reduction control signals for controlling DC offset reduction transistors included in a TFS, such as the TFS shown in FIG. 14 or 15.

FIG. 17 is a schematic of one embodiment of a passive network with tunable elements for use in a TFS.

FIG. 18 is a schematic of one embodiment of a tunable element, implemented as a switched capacitor array in combination with a varactor.

FIG. 19 is a schematic of a tunable current-mode filter implemented using a cascaded series of TFSs.

FIG. 20 is a block diagram of a tunable current-mode filter that includes or is associated with another embodiment of calibration and control circuitry.

FIG. 21 is a block diagram of one embodiment of a current-mode transmit signal chain, that includes a tunable current-mode filter.

### DETAILED DESCRIPTION

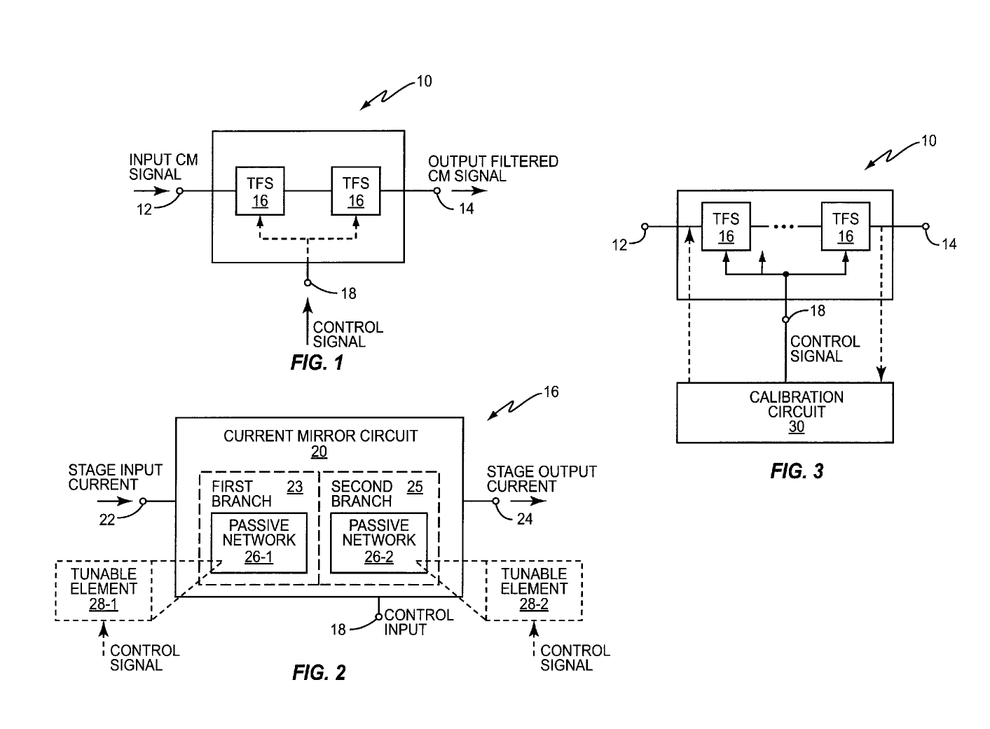

FIG. 1 illustrates one embodiment of a tunable current-mode filter 10, as taught herein. The tunable current-mode filter 10 (“filter 10” for ease of discussion) is implemented as a discrete circuit in one or more embodiments, e.g., individual circuit elements are used, such as discrete transistors, capacitors, etc. In one or more other embodiments, one or more parts of the filter 10 are implemented in an integrated circuit package, which may be a monolithic IC or may be a packaged multi-chip module. Integrated circuit implementations are particularly advantageous in embodiments where the filter 10 includes calibration control features and/or where it is used within a signal processing chain, e.g., a wireless communication transmitter chain, which includes one or more integrated circuit devices.

However, before describing implementations of the filter 10 in example application contexts, it may be helpful to step through representative details depicted for the filter 10 in FIG. 1. One sees that the depicted embodiment of filter 10 comprises a filter input 12, for receiving an input current signal, a corresponding filter output 14, for providing a filtered output current signal, and at least two cascading tunable filter stages 16 interposed between the filter input 12 and the filter output 14, for filtering the input current signal to thereby obtain the filtered output current signal according to a tunable frequency response. (“TFS” is used in the illustration to denote “tunable filter stage.”) Multiple, cascade-connected tunable filter stages 16 may be implemented within the filter 10, to construct higher-order filters.

Each tunable filter stage 16 is configured to have an adjustable frequency response that is changed by changing the value of a control signal applied to the control input 18 of the filter 10. The overall frequency response of the filter 10 therefore is adjustable, i.e., tunable, by manipulation of the control signal value. As non-limiting examples, the filter 10 is configured so that any one or more of its bandwidth, its cutoff frequency, etc., are adjustable. Note that in one preferred embodiment, the filter 10 comprises a low pass filter, and the tunable filter stages 16 included in it are adjustable in terms of cutoff frequency.

In one or more embodiments, the filter 10 comprises a tunable current-mode low pass filter, having at least two cascading tunable filter stages 16 within the filter 10 that are configured to have an adjustable cutoff frequency responsive to the control signal. As such, the overall cutoff frequency of the filter 10 is settable via the control signal. The two or more tunable filter stages 16 are in cascade connection between the filter input 12 and the filter output 14, and, as noted, the order of the filter 10 is a function of the number of tunable filter stages 16 included in the filter 10. Further, in at least one such embodiment, a tunable element (not shown in FIG. 1) in each tunable filter stage 16 comprises a capacitor circuit having a variable capacitance that is set or otherwise adjusted responsive to the control signal.

The filter 10 can be configured to have a desired filter order (for tailoring sharpness, and/or pass band or stop band characteristics) based on the number of cascaded tunable filter stages 16 that are included, and based on the filter order of each included filter stage 16. As such, the overall filter order can be increased or decreased by implementing the filter 10 with a greater or fewer number of tunable filter stages 16, in cascade connection between the filter input 12 and the filter output 14.

FIG. 2 depicts one embodiment of the tunable filter stage 16, wherein it comprises a current mirror circuit 20 that is configured to generate a stage output current by mirroring a stage input current. The stage input current is input to the tunable filter stage 16 via a stage input 22, while the stage output current is output from the tunable filter stage 16 via a stage output 24. In more detail, the current mirror circuit 20 has first and second branches 23 and 25 that are configured to generate the stage output current by mirroring the stage input current. The current mirror circuit 20 includes two passive networks 26-1 and 26-2, one coupled to an output of the first branch 23 and the other one coupled to an output of the second branch 25 of the current mirror circuit. Each passive network includes a tunable element that is operative to adjust a frequency response of the tunable filter stage 16 responsive to a control signal, and thereby adjust an overall frequency response of the tunable current-mode filter 10. In the illustration, current mirror branch 23 includes passive network 26-1, having a tunable element 28-1, while current mirror branch 25 includes passive network 26-2, having a tunable element 28-2. The control signal applied to the control input 18 may be distributed to or otherwise coupled to each tunable element implemented within the tunable filter stage 16.

For the first cascaded filter stage in the filter 10, the stage input current is the input current signal applied to the filter input 12. For the last cascaded filter stage in the filter 10, the stage output current is the filtered output current signal provided at the filter output 14. Intermediate filter stages-those between the first and last-interconnect together.

Each tunable element 28 generally comprises a variable reactance, such as a variable capacitor. For example, a varactor or switched capacitor array, or combination of both, may be used to make a tunable element having a capacitance that varies as a function of the value of the applied control signal. The tunable element 28 in each passive network 26 (“26” is used when the discussion generally relates to passive networks 26-1 and 26-2) is operatively associated with the control input 18, such that changing the value of the control signal changes the reactance of each variable reactance circuit and thereby adjusts an overall frequency response of the filter 10.

The overall frequency response of the filter 10 may be set, for example, by a calibration circuit included in or otherwise associated with the filter 10. Such an embodiment is shown in FIG. 3, where a calibration circuit 30 is shown in association with the filter 10. Broadly, the calibration circuit 30 is configured to detect the overall frequency response of the filter 10, such as in comparison with a desired overall frequency response. As will be explained, the calibration circuit 30 may directly detect the actual overall frequency response of the filter 10 and compare it with a desired frequency response, or it may detect a parameter that is related to the overall frequency response of the filter 10 and compare that detected parameter to a like parameter associated with the desired frequency response.

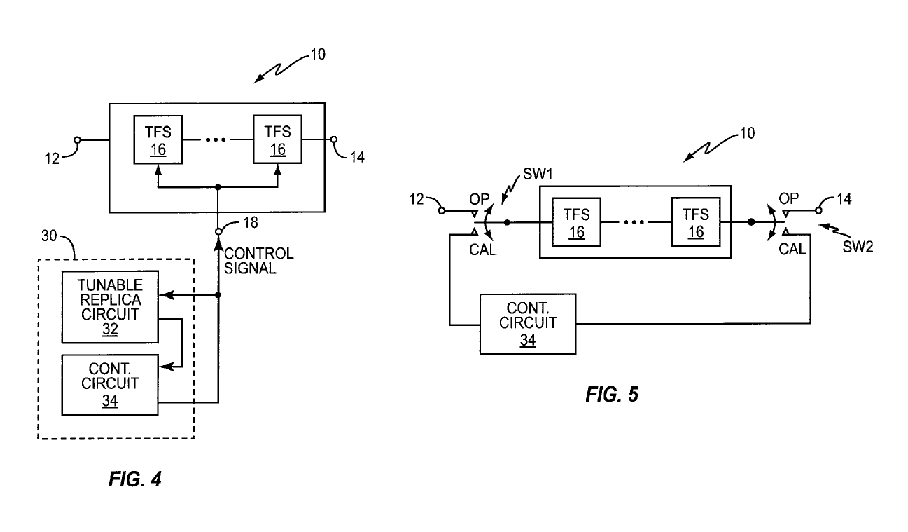

With reference to FIG. 4, detecting the overall frequency response of the filter 10 in one or more embodiments comprises indirectly detecting the overall frequency response (or detecting a parameter related thereto) of the filter 10, based on a tunable replica circuit 32. The tunable replica circuit 32 is configured to operate as surrogate for the filter 10, such that the overall frequency response of the tunable replica circuit 32 has a known relationship to the overall frequency response of the filter 10, and such that observing changes in the overall frequency response of the tunable replica circuit 32 in response to changing control signal values serves as a basis for determining the control signal value needed to adjust the filter 10 to a desired overall frequency response.

The tunable replica circuit 32 may be identical to the filter 10, e.g., it may use an identical number of TFSs 16 of identical configuration, as are used in the filter 10, or it may use a smaller number of TFSs and/or use TFSs based on smaller-geometry devices, for size savings. In any case, the relationship between the frequency response of the tunable replica circuit 32 and the filter 10 is known. Also, in integrated circuit implementations, it is advantageous to implement circuitry for the filter 10 and for the tunable replica circuit 32 in the same semiconductor die area, for good matching.

In operation, the circuitry of FIG. 4 “calibrates” or otherwise “tunes” the filter 10 based a control circuit 34 observing the frequency response of the tunable replica circuit 32, and making corresponding adjustments to the control signal. As the control signal is commonly applied to the filter 10 and the tunable replica circuit 32, and as the frequency response of the tunable replica circuit 32 tracks that of the filter 10 in accordance with a known relationship (e.g., a known proportionality), the control circuit 34 sets the filter 10 to a desired overall frequency response by adjusting the control signal as needed to achieve a desired frequency response for the tunable replica circuit 32.

With the arrangement of FIG. 4, tuning can be done essentially at any time, because the tunable replica circuit 32 provides the basis for observation, and the filter 10 need not be taken out of service. (Of course, to the extent that control signal adjustments may not be desirable during some operational times, tuning times may still be restricted.) In one such embodiment, the calibration circuit 30 includes an oscillator circuit (not shown in FIG. 4) that is configured to have an oscillation frequency dependent on the overall frequency response of the tunable replica circuit 32. The calibration circuit 30 is configured to detect the overall frequency response of the filter 10 by detecting the oscillation frequency of the oscillator circuit. Such detection may be indirect, such as by monitoring the oscillation frequency of the oscillator.

In other words, the calibration circuit 30 uses the detected oscillation frequency to infer the frequency response of the tunable replica circuit 32 and/or the filter 10, and makes corresponding control signal adjustments. To do so, the tunable replica circuit 32 is placed in a feed-back loop to form an oscillator circuit having an oscillation frequency dependent on the overall frequency response of the tunable replica circuit 32. Correspondingly, the calibration circuit 30 is configured to detect the overall frequency response of the tunable current-mode filter 10 by detecting the oscillation frequency of the oscillator circuit.

FIG. 5 illustrates an alternative embodiment where tuning requires less circuitry, i.e., the tunable replica circuit 32 is omitted, but where tuning takes the filter 10 out of service temporarily. In FIG. 5, tuning is based on observing the behavior of the filter 10, rather than the behavior of a surrogate circuit. As such, the filter 10 may be implemented with “switches” SW1 and SW2 at its filter input 12 and filter output 14, so that the filter 10 can be switched from an operational mode (the “OP” switch position) to a calibration mode (the “CAL” switch position). Those skilled in the art will appreciate that the switches SW1 and SW2 can be electronic devices, such as MOS transistors, and or other active circuits that provide for selective electrical coupling and blocking (e.g., high impedance operation). Also, the filter 10 may be included in a signal processing chain that allows for tuning of the filter 10 without the need for isolating its input 12 and output 14 from associated signal chain circuits. Thus, some implementations can eliminate the input isolation switch SW1, or the output isolation switch SW2, or both.

In one embodiment of FIG. 5, the calibration circuit 30 comprises a digital processor configured to detect the overall frequency response of the filter 10 by detecting an oscillation frequency of an oscillator circuit (not shown in FIG. 5), where the oscillation frequency is dependent on the overall frequency response of the filter 10. As noted regarding switches SW1 and SW2, such embodiments may include one or more isolation circuits operable by the digital processor and configured to place the filter 10 during a first time into a calibration mode. In calibration mode, the filter 10 operates as part of the oscillator circuit for detection of the overall frequency response of the filter 10, and the digital processor makes corresponding adjustments of the control signal. Further, isolation circuits are operable to place the filter 10 during a second time into an operation mode, e.g., “live” signal filtering, wherein it provides current-mode filtering as part of a signal processing chain. Such embodiments are particularly advantageous where the signal processing chain has a capable digital processor already available, such as the baseband digital processor very typically included in wireless communication devices like cellular radiotelephones, etc.

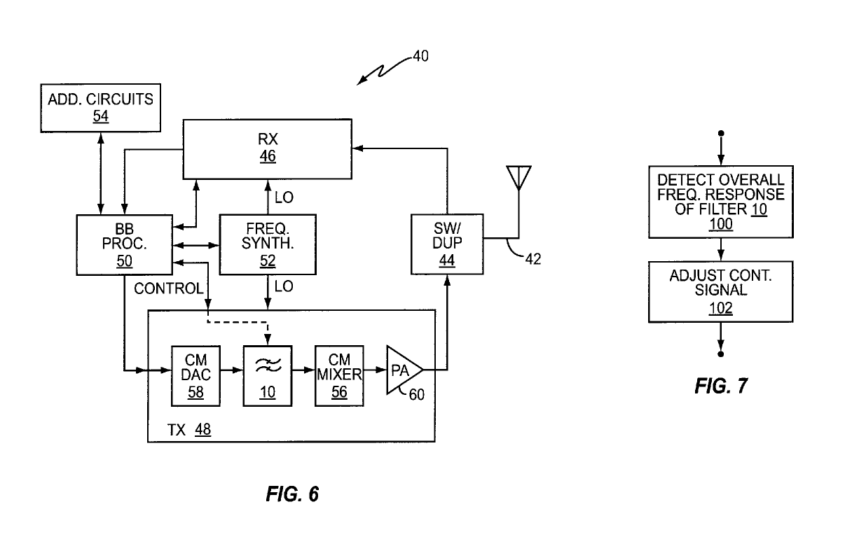

Indeed, FIG. 6 illustrates an embodiment of the filter 10, wherein it is implemented in the transmit signal processing chain in a wireless communication device 40. In the non-limiting example illustration, the wireless communication device 40 comprises one or more transmit/receive antennas 42, a switch/duplexer 44, a receiver 46, a transmitter 48, a baseband digital signal processor (BB proc.) 50, a frequency synthesizer 52, and optionally other circuits such as system control (e.g., a microprocessor-based overall control circuit) and user interface circuits 54.

The overall transmitter as represented by the baseband processor 50 and the transmitter circuitry 48 is of particular interest. The illustrated transmitter circuitry 48 includes a current-mode mixer 56 that is configured to generate a transmit signal by modulating a carrier frequency signal according to a filtered current-mode information signal, and correspondingly includes an embodiment of the filter 10, here configured to generate the filtered current-mode information signal by filtering a current-mode information signal. Advantageously, the overall frequency response of the filter 10 is tunable responsive to a control signal.

Further, the transmitter circuitry 48 includes a current-mode digital-to-analog converter (DAC) 58 that is configured to generate the current-mode information signal, for input to the filter 10, from a digital baseband information signal, which may be generated by the baseband processor 50. The overall transmitter further includes a control circuit configured to adjust the control signal according to a desired frequency response for the filter 10. In the illustrated embodiment, the baseband processor 50 is configured to operate as the controller, with the configuration implemented via hardware, software, or a combination thereof.

Whether implemented via the baseband processor 50 within the wireless communication device 40, or implemented in another type of device or system, a method of filter operation is contemplated herein. Particularly, this disclosure broadly presents a method of adjusting frequency response in a signal processing chain that includes a filter 10 having an overall frequency response adjustable as a function of a control signal applied to it. In one or more embodiments, the method, such as shown in the logic flow diagram of FIG. 7, comprises detecting an overall frequency response of the tunable current-mode filter (Block 100), and adjusting the control signal as needed according to a desired overall frequency response (Block 102).

In at least one such embodiment, detecting the overall frequency response of the filter 10 comprises directly or indirectly detecting an overall delay time of the tunable current-mode filter. That detection can be accomplished using a phase/frequency detector, such as where the phase delay between a reference signal and a filter-dependent oscillator signal is used to generate a proportional error signal. Also, as explained before, detecting the overall frequency response of the filter 10 may comprise detecting an overall frequency response of a tunable replica circuit (such as shown in FIG. 4) operating as a surrogate for the filter 10 and responsive to the control signal in like manner as the filter 10. The detection thus may comprise detecting an oscillation frequency that depends on the overall frequency response of the tunable replica circuit.

Alternatively, as explained earlier, detecting the overall frequency response of the filter 10 comprises temporarily placing the filter 10 into a calibration mode and therein detecting an oscillation frequency that is dependent on the overall frequency response of the filter 10 and correspondingly adjusting the control signal according to a desired overall frequency response. As illustrated in the example of FIG. 6, detecting the overall frequency response of the filter 10 may be performed using a digital signal processor included in the signal processing chain, where the processor is configured to generate or otherwise control generation of an analog current-mode signal that is filtered by the filter 10, at least when the filter 10 is not operating in the calibration mode.

Of course, those skilled in the art will appreciate that use of the filter 10 within signal processing chains that have intelligent control offers significant flexibility for implementing various calibration (also understood as “tuning”) procedures. Calibration can be performed at power-on, or when operating parameters change, such as when bandwidth assignments are changed for a cellular radiotelephone (as is done in LTE), or when environmental conditions (e.g., temperature) change beyond given thresholds. Calibration also may be one-time, such as during device manufacture or initialization. Indeed, as one particular advantage, the filter 10 can be configured with tunable elements 28 that allow its overall frequency response to be tuned into a desired range and then fixed at that tuned configuration setting. For example, the control signal may not be generated as a dynamic signal, but rather it may be fixed by setting fuse elements or the like, such that the control signal allows an initial tuning of the filter 10, which can be held permanently, with or without battery power. This approach allows the production tolerances of the filter 10 to be relaxed, because no such filter 10 need be rejected unless its calibration fails, or it fails in some other performance/quality check.

The foregoing teachings have detailed cascade current mode low pass filters, with variable pass band width and bandwidth calibration techniques. Such teachings may be summarized as using a current mirror to build a single current mirror stage containing 2m-pole low pass filters (LPF), and then building higher order current mode low pass filters (CMLPFs) by cascading n stages of the single current mirror stage of 2m-pole LPF—i.e., implementing filter 10 by cascading two or more 2m-pole LPFs. Employing variable tunable capacitor arrays in the single current mirror stage of the 2m-pole LPFs makes the overall bandwidth of the resulting filter 10 tunable.

Thus, an implementing system can detect the delay time of the CMLPF, or detect the delay time in a replica of the CMLPF, and determine the cut-off frequency of the CMLPF. The CMLPF is then tuned for the desired bandwidth by adjusting the capacitance of the capacitor arrays included in the n cascaded 2m-pole LPFs comprising the CMLPF. With the introduction of this approach as presented herein, the design of CMLPF has advantageous simplicity, and power consumption can be reduced as compared with voltage mode counterparts. As one example of power reduction, the CMLPF teachings herein eliminate feedback loops in the filter structure, meaning that circuit speed requirements are relaxed, as compared to feedback loop based voltage mode filter structures.

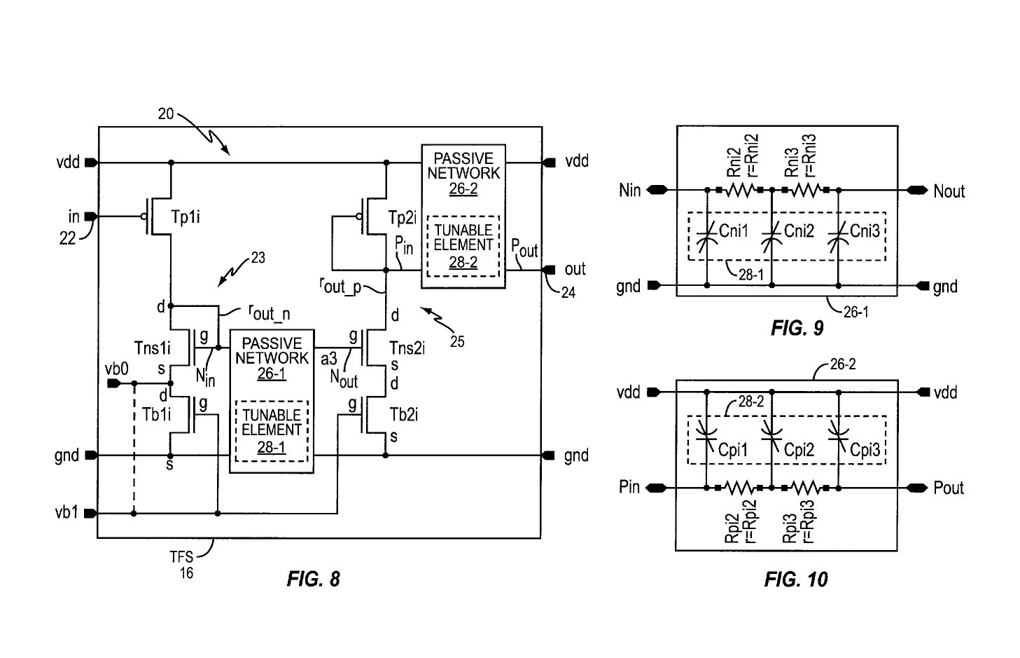

Thus, a high order CMLPF implementation of the filter 10 can be built by implementing the TFSs 16 as cascaded single current mirror stages, each containing a 2m-pole low pass filter. (As examples, m=1, 2, or 3.) A first type of current mirror circuit is shown in FIG. 8, wherein one embodiment of the TFS 16 is shown, configured as a 2m-pole low pass filter. (Of course, those skilled in the electrical arts will recognize from this disclosure that other kinds of current mirrors are also possible for forming 2m-pole low pass filters.) Also, those skilled in the art will appreciate that all TFSs 16 included in the filter 10 can be like that shown in FIG. 8, or different implementations can be used for two or more of the TFSs 16. For example, the input and/or output stage may be modified to facilitate interconnection with external circuitry. Indeed, in at least one embodiment, the filter 10 can be implemented with multiple filter stages, including a mix of TFSs 16, and non-tunable but otherwise similar current-mirror filter stages.

In any case, according to the details shown in FIG. 8, the TFS 16 comprises a current mirror circuit 20, including the various illustrated transistors comprising branches 23 and 25, and two passive networks 26-1 and 26-2, respectively including tunable elements 28-1 and 28-2. The passive networks 26 and tunable elements 28 may be the same or may be different, and the use of different reference numbers primarily is for convenience of differentiating the locations within the current mirror circuit 20 at which the passive networks 26-1 and 26-2 are integrated.

The current mirror circuit 20 has two transistor branches, the first branch 23 with transistors Tp1i, Tns1i and Tb1i, and the second branch 25 with Tp2i, Tns2i and Tbi2. The transistors Tp1i and Tns2i are the driving transistors which provide transconductance at a given gate voltage. The transistors Tns1i and Tp2i are the active load transistors which sink the current created by the driving transistors. The output impedance, denoted as “rₒᵤₜ_{_{—}}ₙ” and “rₒᵤₜ_{_{—}}ₚ”, at the output nodes of each branch, such as at the drain nodes of Tns1i and Tns2i, is parallel of the output impedance of the driving transistor Tp1i/Tns2i and the input impedance of the load transistor Tns1i/Tp2i. For further signal path reference, the stage input 22 is the input port labeled “in” and the stage output 24 is labeled “out,” while “vb1” denotes the bias terminal, and vdd and gnd are connected to power supply and ground nets separately.

The bias voltage vb1 can be connected to logic high or low, providing high impedance as source degeneration resistor when connected to logic high, or behaving as enable control which enables the LPF at logic high. Otherwise, the branch is shut down. In another configuration, the bias voltage vb1 is connected to node vb0, as shown in the illustration by the dashed connection line, for a self biasing implementation, which makes the driver transistor have higher output impedance.

The passive filter networks 26-1 and 26-2, configured here for low pass filtering, can each have m capacitors and m−1 resistors. The 2m−1 passive components, together with the output impedance of the transistor branch, form an m-order passive low pass filter. When m=1, the network is degraded to a first-order low pass filter, hence only one capacitor is required, i.e., either capacitor Cni1 shown in the tunable element 28-1 of the passive network 26-1 in FIG. 9, or the capacitor Cpi1 shown in the tunable element 28-2 of the passive network 26-2 in FIG. 10. On that point, it should be understood that “tunable element 28” as referred to herein may be implemented using a single adjustable component, or may be implemented via a network of adjustable components. Thus, as regards the passive network 26-1, the tunable element 28 includes variable capacitors Cni1, Cni2, and Cni3. Likewise, the tunable element 28 for the passive network 26-2 should be understood as including the variable capacitors Cpi1, Cpi2, and Cpi3. The tunable element 28-1 may or may not be the same as the tunable element 28-2, although both generally are responsive to the control signal, as applied to the control input 18.

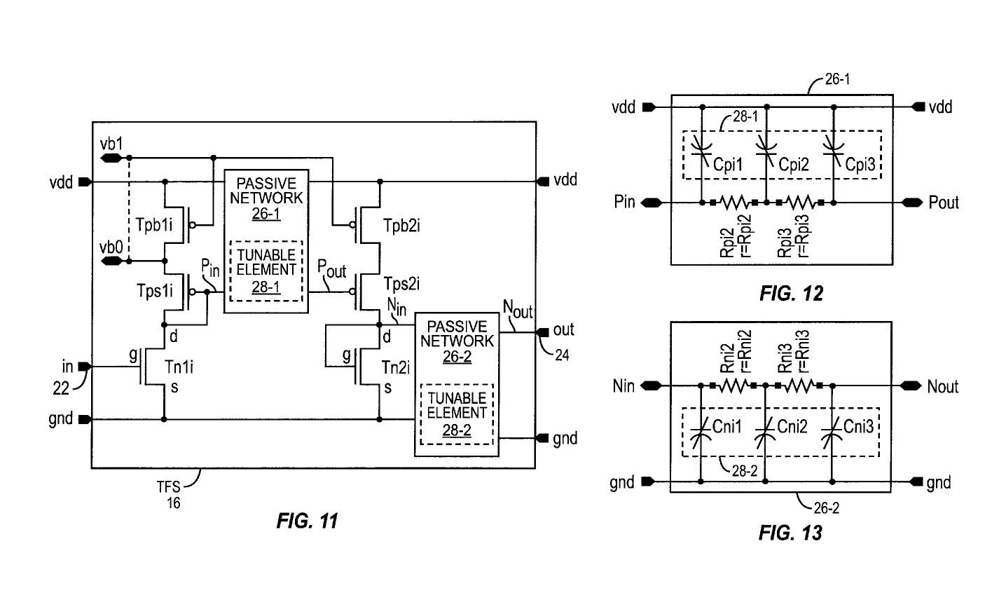

FIG. 11 illustrates another embodiment of the TFS 16, which differs from the implementation in FIG. 8 by swapping the N and P transistors and power nets. FIGS. 12 and 13 correspondingly illustrate passive networks 26-1 and 26-2, for use in the TFS 16 of FIG. 11.

As before, the current mirror circuit embodied in the TFS 16 of FIG. 11 includes two transistor branches, the first with transistors Tn1i, Tps1i and Tpb1i, and the second with Tp2i, Tns2i and Tbi2. The transistors Tn1i and Tps2i are the driving transistors which provide transconductance at a given gate voltage. The transistors Tps1i and Tn2i are the active load transistors which sink the current created by the driving transistors.

The bias voltage vb1 can be connected to logic high or low, providing high impedance as source degeneration resistor when connected to logic low, or behaving as enable control which enables the LPF at logic low. Otherwise, the branch is shut down. Alternatively, as before, the bias voltage vb1 can be connected to node vb0 (dashed line connection), for self-biasing, which makes the driver transistor have higher output impedance. Of course, those skilled in the art will recognize other current mirror and passive network circuit variations, which nonetheless do not depart from the basic current-mode filtering approach exemplified by FIGS. 8 and 11.

For example, the current mirrors may be implemented to minimize DC offsets and the corresponding changes in transistor operating points. In ideal current mirrors, the driving transistors should have infinitive high output impedance and the load transistors should have zero input impedance. However, in reality, because the driving transistors have limited output impedance and the load transistors have non-zero input impedance, a small DC offset voltage will be added to output node of the current mirror shown in FIGS. 8 and 11.

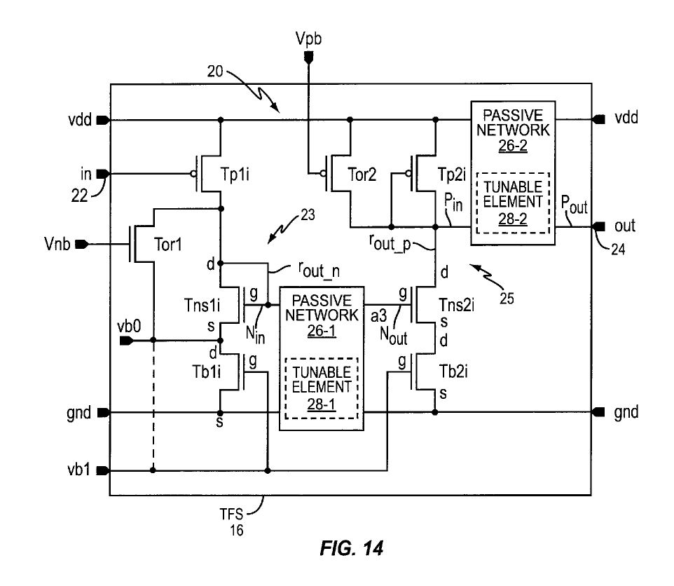

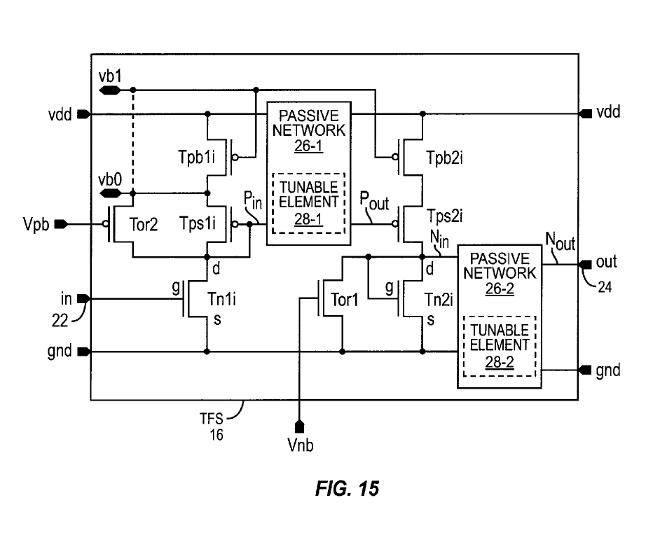

Even with small DC offsets, the issues arising from changed transistor operating points can become significant where two or more current mirror stages are cascaded together. FIG. 14 illustrates a modified version of the current mirror circuit shown in FIG. 8, and FIG. 15 likewise illustrates a modified version of the current mirror circuit shown in FIG. 11.

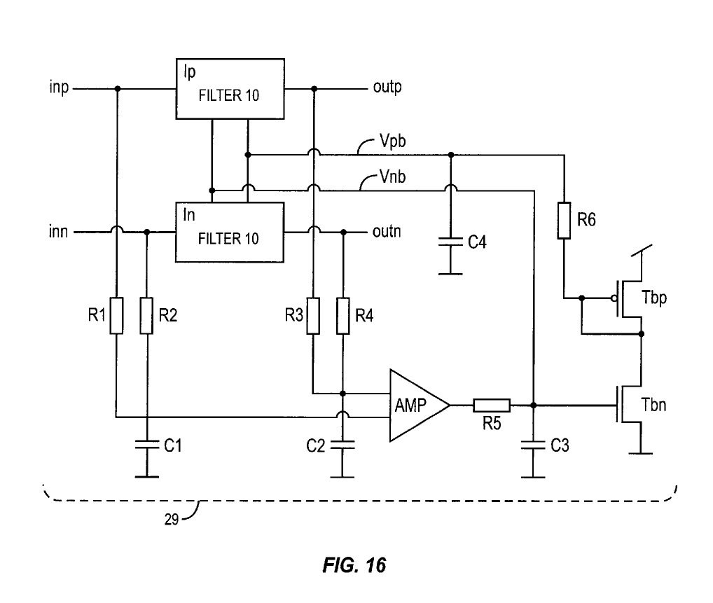

These modified current mirror circuits provide advantageous reductions in DC offset. In particular, the added offset reduction transistors (Tor1 and Tor2) leak the current introduced by the limited output impedance in current mirrors and thereby cancel or at least significantly reduce DC offset. FIG. 16 presents additional DC offset reduction circuitry that can be used advantageously with the modified current mirrors shown in FIGS. 14 and 15.

In the context of FIG. 16, DC offset is the DC voltage difference between the input nodes inp and inn and the output nodes outp and outn. The DC offset can be detected in the illustrated circuit arrangement and removed by using current mirror circuit configurations shown in FIG. 14 or 15, which include offset reduction transistors Tor1 and Tor2. For simplicity, only one of the two quadrature channels is shown.

In operation, the input differential signals inp and inn are added together through resistors R1 and R2, and capacitor C1 removes the signal ripples and keeps the DC common mode voltage at the input of the two filters 10 (the Ip filter 10 and the In filter 10). In a similar way, the output differential signals outp and outn will be added together through resistors R3 and R4, where capacitor C2 removes the signal ripples and keeps the DC common mode voltage at the output of the filters Ip and In. The DC offset voltage is detected in the inputs of the amplifier Amp, and it is amplified to create the control signal Vnb used in the circuits shown in FIG. 14 and FIG. 15 in the N current branches. Similarly, the control signal Vpb is created by transistors Tbn and Tbp, and applied to the P current branches as shown in FIGS. 14 and 15.

The various circuit elements, e.g., the amplifier Amp, transistors Tbp, Tbn, resistors R1-R6, capacitors C1-C4, and their illustrated interconnections, function together as an offset detection circuit 29, which provides control signals to the offset reduction transistors Tor1 and Tor2, as shown in FIG. 14 or 15. Such operation represents a feedback loop that removes the DC offset between the input nodes and output nodes of the current mode low pass filters 10, and one may note that resistor/capacitor R5/C3 and resistor/capacitor R6/C4 form two low-pass filters, which filter noise from the feedback control signals Vnb and Vpb. Thus, in at least one embodiment, a tunable current-mode filter 10 as taught herein includes or is associated with a DC offset detection circuit, e.g., circuit 29, that is configured to generate an offset reduction control signal responsive to detecting DC offset in at least one of the tunable filter stages 16 of the tunable current-mode filter 10. Each such tunable filter stage 16 includes an offset reduction transistor that is configured to reduce DC offset within the stage, responsive to the offset reduction control signal (e.g., Vnb or Vpb).

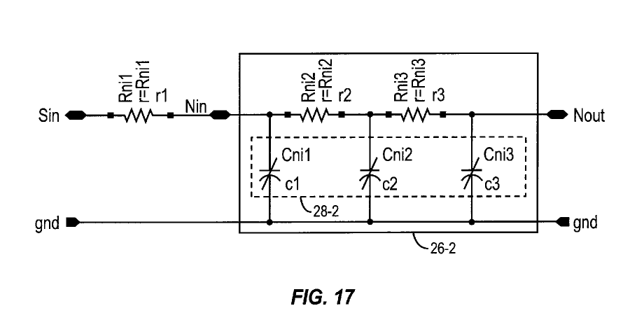

Turning to further circuit details, FIG. 17 provides a more detailed example illustration of the passive network 26-2, with its tunable element 28-2, as was introduced in FIG. 2. (The same or similar configuration can be used for the passive network 26-1.) The illustrated implementation comprises a passive 3-pole LPF configuration. With this configuration, one may denote the associated current mirror circuit transistor branch as having an output impedance of r₁, which is the impedance at the output nodes of the transistor branches. Then, for the illustrated passive network 26-2, the voltage transfer function (expressed in Laplace domain) is given as,

$$V ( s ) = \frac{Nout ( s )}{Sin ( s )} = \frac{1}{{T}_{3} {s}^{3} + {T}_{2} {s}^{2} + {T}_{1} s + 1} \\ where \\ {T}_{3} = τ 1 τ 2 τ3 \\ {T}_{2} = τ1τ2 + τ1τ3 + τ2τ3 + τ1τ23 + τ12τ3 \\ {T}_{1} = τ1 + τ2 + τ3 + τ12 + τ13 + τ23 \\ τ1 = {r}_{1} {c}_{1} , τ2 = {r}_{2} {c}_{2} , τ3 = {r}_{3} {c}_{3} , \\ τ12 = {r}_{1} {c}_{2} , τ13 = {r}_{1} {c}_{3} , τ23 = {r}_{2} {c}_{3} \qquad Eq . ( 1 )$$

With proper selection of parameters, the LPF response can be optimized on certain criteria of interest.

When r₃ and c₃ become zero, the transfer function is simplified to

$$V ( s ) = \frac{Nout ( s )}{Sin ( s )} = \frac{1}{{T}_{2} {s}^{2} + {T}_{1} s + 1} \\ where \\ {T}_{2} = τ1τ2 \\ {T}_{1} = τ1 + τ2 + τ12 \qquad Eq . ( 2 )$$

Thus, the response is a 2nd-order LPF. Also, if r₂>>r₁, and one keeps the same time constant, the two filter poles are approximately located at

$$- \frac{{τ}_{1}}{{τ}_{1} {τ}_{2}} and - \frac{{τ}_{2}}{{τ}_{1} {τ}_{2}} .$$

In fact, the term T₁ is the Elmore delay, which is a known basis for calculation of the delay time in digital circuit design. If r₁=r₂=r, and c₁=c₂=c, then T₁ becomes 3τ₁. Normally, the larger the Elmore delay, the more “lossy” is the network. In this case, the transfer function has two different real poles. Further, when r₂ and c₂ become zero, the passive filter is degraded into a first-order LPF. Therefore, the voltage mode transfer function becomes

$$V ( s ) = \frac{Nout ( s )}{Sin ( s )} = \frac{1}{{τ}_{1} s + 1} \qquad Eq . ( 3 )$$

In general, the filter noise increases as the filter order of the passive network 26 is increased. On the other hand, using higher-order implementations of the passive network 26 allows fewer cascaded TFSs 16 to be used in implementing the filter 10, for a given overall filter order. A designer may therefore consider noise, filter quality, and power, among other things, when determining the particular implementation of TFSs 16 versus the number of TFSs 16 to cascade.

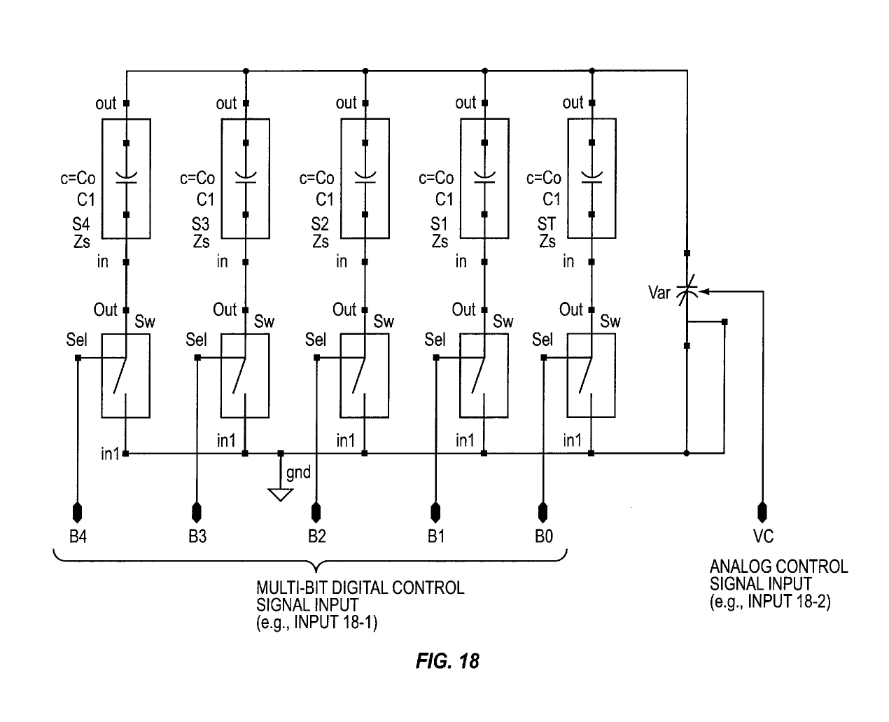

Further flexibility exists with respect to tunable element implementation. For example, one or more of the capacitors in the passive network(s) 26 included within one TFS 16 can be fixed for fixed bandwidth, or can have variable capacitance for variable bandwidth. In a non-limiting but advantageous embodiment, the variable capacitance is implemented using a switched capacitor array and/or a varactor, as shown in FIG. 18.

One sees a number of switches (“Sw”) that are operable responsive to individual bit lines within a multi-bit control signal input. The control signal may comprise a digital word, the binary pattern or value of which determines which capacitors in the array are switching in or out of parallel connection. For example, a control input 18-1 can be configured as a digital control word input, for capacitor array switch actuation. (The same control word can be distributed to other capacitor arrays in other TFSs 16 within the filter 10.) The array capacitors may be the same value, or may have different values complementing binary (step-change) capacitance adjustment.

One also sees that the control signal can also include an analog control signal, such as applied to a control input 18-2, for adjusting the capacitance of a varactor (“Var” in the figure). Those skilled in the art will appreciate that other reactance devices may also be varied with analog control inputs. As just one example, the analog control signal is a voltage-mode signal, where the voltage value corresponds to a given capacitance setting for the varactor.

In the illustrated configuration, the control input 18-1 comprises a 5-bit wide control bus B[0:4], which provides coarse capacitance adjustment via control of the switched capacitor array. Complementing this coarse control the control input 18-2 provides finer, analog control of the varactor Var. Thus, a frequency response adjustment algorithm can be implemented to make coarse frequency response adjustments for the filter 10 via changing the binary value of the digital control word applied to the control input 18-1, and to make finer frequency response adjustments via changing the value of the analog control signal applied to the control input 18-2.

A digital processor can, for example, be programmed or otherwise configured to make coarse up/down control changes until the desired frequency response for the filter 10 is bracketed by two coarse adjustment values, and thus use the finer analog control signal to move up (or back down) to an intermediate, finer setting between those two coarse settings. Of course, in some applications, the switched capacitor array or the varactor can be used alone. In any case, the bandwidth of the filter is inversely proportional to the total adjusted capacitance.

Broadly, then, the passive network(s) use at least one TFS 16 as the basic building block for the filter 10 presented herein preferably comprises m reactive components, where m is an integer>1, and m−1 resistive components, that are operative in conjunction with transistor output impedances of the TFS's current mirror circuit to form an m-order low pass filter circuit. At least one of the m reactive components comprises a tunable element 28.

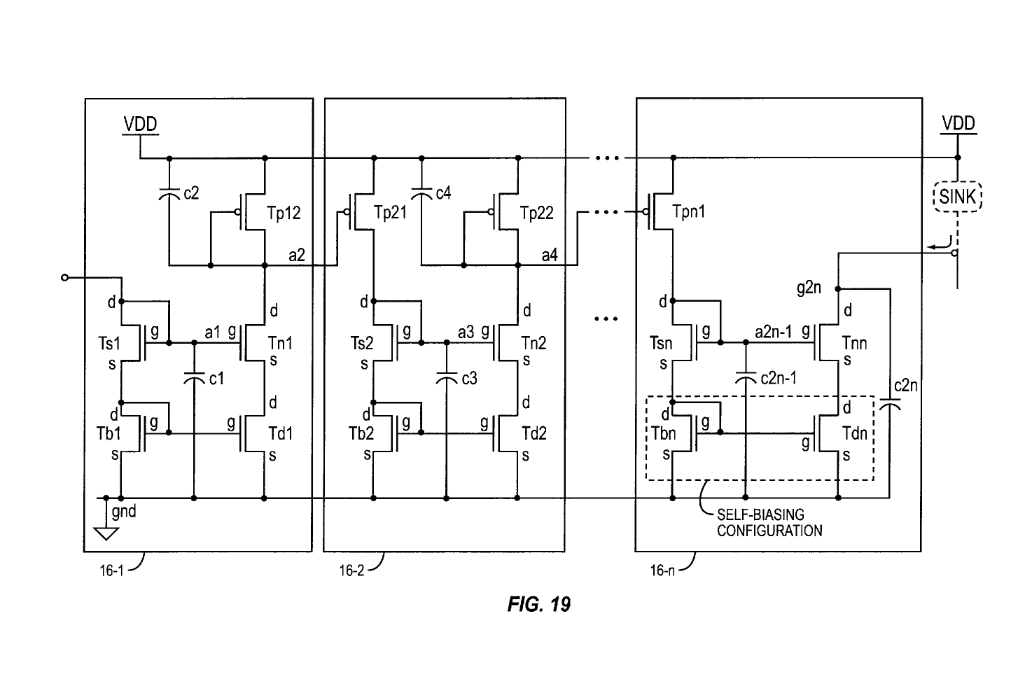

FIG. 19 illustrates an example multi-stage CMLPF implementation of the filter 10, built by cascading n stages of 2m-pole TFSs 16 together. This approach can be used to achieve desired filter performance, providing good frequency attenuation at stop band. The DC offset reduction parts presented in FIG. 14, FIG. 15 and FIG. 16 are not shown in FIG. 19.

In particular, FIG. 19 illustrates n-stages of TFSs 16. TFS 16-1 is the first TFS in the cascade chain, and 16-n is the last stage in the chain. (TFS 16-n is implemented with slight modifications, to provide convenient current sink connection to an external circuit. Of course, with a linear resistor to replace the current sink, the output current could be converted to an output voltage. One also sees that FIG. 19 presents a simplified view of the passive networks 26, which are not shown by reference number in FIG. 19. Instead, the passive network(s) in TFS 16-1 are represented by the capacitors C1 and C2, one or both of which are variable capacitors. Similarly, the capacitors C3 and C4 in TFS 16-2 are the passive network(s) for the second stage, and the capacitor C2n-1 in TFS 16-n is the passive network for the last, output stage.

In another variation, the filter 10 is implemented with its input 12 configured for a differential current-mode input signal, and its output 14 configured for outputting a filtered, differential current-mode output signal. Constructing a differential version of the filter 10 with its one or more included TFSs 16 is accomplished by duplicating the illustrated circuit topology, to create two paralleled filters that are opposite in polarity for the differential input current source.

As a further implementation point, it may be noted that the output stage (the final TFS 16-n) may be desired to occupy no higher voltage room than necessary for any active devices tied to the output 14 of the filter 10. Therefore, the transistors Tbn and Tdn as shown in FIG. 19 can be removed by connecting the source nodes of transistors Tsn and Tnn directly to the ground. The same technique can be applied to other TFSs 16 making up the filter 10, for use in low supply voltage applications.

Regardless of these implementation variations, it is of interest to assess example performance for an embodiment of the filter 10 built from cascaded TFSs 16. To aid that assessment, one may assume that all poles in the TFSs 16 are the same, say

$${ω}_{p} = \frac{1}{τ} = \frac{1}{rc} .$$

Then, the overall frequency transfer function of the k-order filter 10 becomes

$$H ( ω ) = {\prod }_{i = 1}^{k} \frac{1}{{( 1 + jτω )}^{i}} = \frac{1}{{( 1 + jτω )}^{k}} \qquad Eq . ( 4 )$$

And, the 3 dB cut-off frequency for the filter 10, ω_{c}, is then determined by setting

$$\vert H ( {ω}_{c} ) \vert = \vert \frac{1}{{( 1 + {jτω}_{c} )}^{k}} \vert = \frac{\sqrt{2}}{2} \qquad Eq . ( 5 )$$

With this setting, ω_{c} is given as

$$ω c = \frac{\sqrt{{( 1.414 )}^{\frac{2}{k}} - 1}}{τ} \qquad Eq . ( 6 )$$

The phase shift of the filter 10 with its multi-stage implementation is

θ=−k arctg(ωτ) Eq. (7)

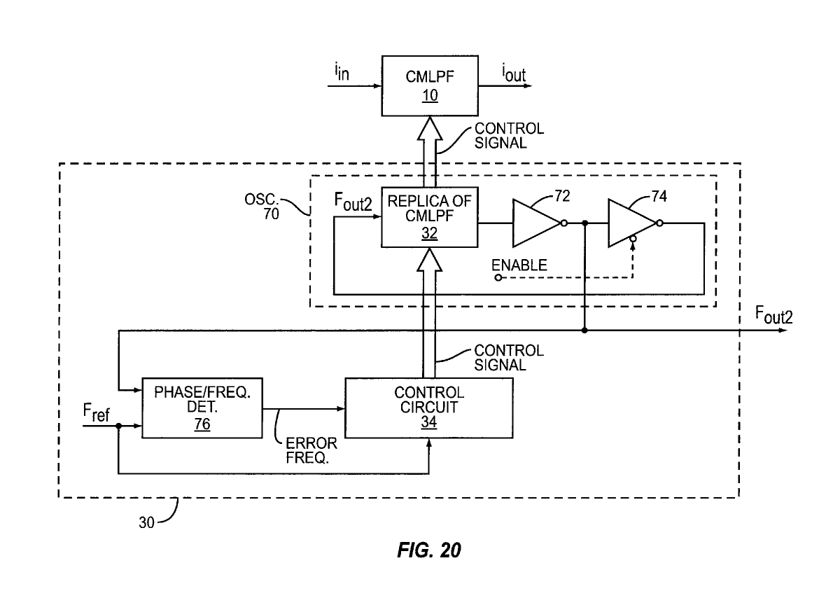

Therefore, according to the teachings herein, the filter 10 and/or associated control circuitry can be configured to detect the overall frequency response of the filter 10 as its 3 dB cut-off frequency, ω_{c}, based on detecting the phase shift of the filter 10. FIG. 20 depicts one embodiment of such detection, and provides further details regarding the circuit configurations and corresponding methods of operation introduced in FIGS. 3-5.

The embodiment of FIG. 20 illustrates a circuit configuration implementing a bandwidth control and track method. The illustrated circuit includes a filter 10 as taught herein, implemented here as a multi-stage CMLPF built with n stages and having current input Iin and current/voltage output IouIVout. The tunable replica circuit 32 operates as a surrogate circuit for the filter 10. In particular, the tunable replica circuit 32 has the same structure, but uses one TFS 16, or at least uses a fewer number of TFSs 16, for simplicity, space reduction, and power reduction. That is, by using fewer TFSs 16, the power consumption of the replica is much less than the working filter 10, but it nonetheless has the same frequency response.

The tunable replica circuit 32 is used to form an oscillator 70, whose oscillation frequency thus depends on the overall frequency response of the tunable replica circuit 32. To complete the oscillator function, the oscillator 70 includes two inverters 72 and 74, placed in series at the output of the tunable replica circuit 32, and configured to feed back into the input of the tunable replica circuit 32. This buffered loop back to the input of the tunable replica circuit 32 forms a positive feedback loop and therefore provides for oscillation. That is, with the help of the two inverters 72 and 74, the loop gain is greater than one, and with a proper phase shift, the depicted circuit behaves as an oscillator. As the inverters 72 and 74 are digital and also have much less delay than the tunable replica circuit 32, the oscillating frequency is mainly determined by the tunable replica circuit 32.

To be resonated at same phase as needed for maintaining oscillation, the phase shift of the tunable replica circuit 32 must be 2π. Thus, we have

$$θ = - k \cdot arc tg ( ωτ ) = 2 π \\ = > {ω}_{0} = \frac{1}{τ} tg ( \frac{2 π}{k} ) \qquad Eq . ( 8 )$$

Where ωₒ is the oscillating frequency of the loop. Of course, an odd number stage of inverters can also be used to ensure oscillation of the loop, in which case the required phase shift is π instead of 2π.

From Eq. (6) and Eq. (8), it may be appreciated that the relationship between the oscillation frequency ωₒ and the filter's cutoff frequency ω_{c} are related as

$$\frac{{ω}_{0}}{{ω}_{c}} = \frac{tg ( \frac{2 π}{k} )}{\sqrt{{( 1.414 )}^{\frac{2}{k}} - 1}} \qquad Eq . ( 9 )$$

Therefore, if ωₒ is detected, then ω_{c} can be calculated from it, such as by executing appropriate computer program instructions in a processor-based embodiment of the control circuit 34. Thus, based on the oscillation frequency detected at node Fout, the appropriate control word vector for a digital control word can be computed, which is operative to change the frequency response of the tunable replica circuit 32 (and the filter 10 in like manner), by changing the capacitance of the tunable elements 28 in the replica circuit 32 (and likewise in the filter 10). Thus, a variable capacitor or other variable reactance circuitry can be updated by the processor to initialize the bandwidth of the filter 10, or to track/monitor its bandwidth during real time operation. In this context, the overall frequency response of the filter 10 is detected by detecting the oscillation frequency of the oscillator 70, where such detection may use a phase or a frequency detector 76 to produce an error signal, and by relating that detected oscillation frequency to the 3 dB cutoff frequency of the tunable replica circuit 32 (and filter 10) according to a known relationship.

Of course, as noted earlier herein with respect to FIG. 5, such detection may be based on placing the actual filter 10 into an initialization mode and detecting its oscillation frequency, and setting its bandwidth during such initialization periods. This approach can be realized by replacing the inverter 74 with a 3-state inverter driver. In initialization mode, the inverter 74 is enabled (via an Enable signal, such as a digital signal controlled by the control circuit 34), while in the operational mode, the Enable signal is set to place the output stage of the inverter 74 into a high-impedance connection that does not inject current into the input of the filter 10.

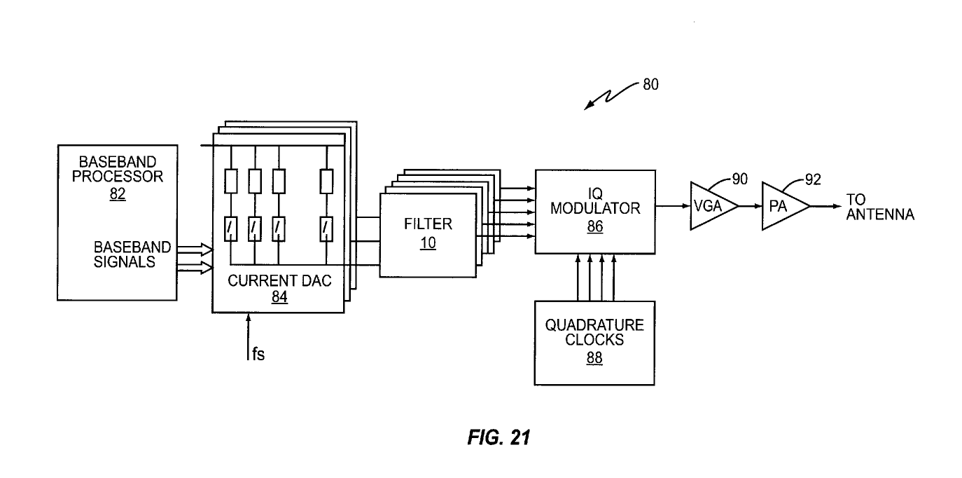

The simplicity and power consumption, along with its tuning/tracking capability, make it an ideal candidate for use in wireless communication transmitter circuits, as described in association with FIG. 6. FIG. 21 provides another example of a current-mode transmit signal chain 80, where a baseband processor 82 generates baseband digital signals, such as I/Q data streams. Differential quadrature current mode DACs 84, operated at a sampling/conversion frequency fs, generate baseband I/Q signals corresponding to the digital I/Q streams output by the baseband processor 82. A differential quadrature embodiment of the filter 10, or parallel implementations of the filter 10, provide filtered current-mode I/Q output signals, based on receiving the current-mode I/Q signals from the DACs 84. These filtered current-mode signals serve as modulating inputs to a current-mode I/Q modulator 86, which is driven by quadrature clock signals from a quadrature clock circuit 88. The modulator output signal drives a variable gain amplifier 90, which in turn drives a power amplifier 92. The power amplifier output signal is routed to transmit antenna(s) for transmission.

Note that the sampling frequency fs of the DACs 84 is chosen several times higher than the maximum Nyquist frequency of the baseband signals, so there is no harmful frequency component created in the transient band of the filter 10. In other words, the baseband signals are over-sampled in the digital format so that there is a large gap between bandwidth of baseband signals and quantization noise spectrum of the DACs 84. Then, the order of the filter(s) 10 can be configured for effectively attenuating the high frequency quantization noise spectrum created by the DAC 84s, to thereby prevent interference with co-located receiver circuitry, and to prevent out-of-band transmissions.

Among the many advantages of the filter 10 and the associated circuits and methods presented herein, it should be understood that use of the filter 10 eliminates current-to-voltage and voltage-to-current conversions, which are typically required in transmitter designs, and thus eliminates the non-linear distortion and noise associated with these conversions. Further, higher order filters, e.g., high-order LPFs, can be built very elegantly using the disclosed current mirror and integrated passive network approach taught herein. These easily obtained high order filter designs provide good attenuation for the higher frequency spectrums associated with over-sampling current-mode DACs. Further, the elegant design of the filter 10 provides lower power consumption as compared to a voltage-mode implementation. Still further, the cut-off frequency or other frequency response parameter of the filter 10 can be easily detected, such as by using the feed-back loop oscillation technique described herein, and the filter's bandwidth can be well controlled or otherwise adjusted using analog and/or digital control signals.

Of course, the present invention is not limited to the foregoing discussion and accompanying drawings. Instead, the present invention is limited only by the following claims and their legal equivalents.

What is claimed is:

1. A tunable current-mode filter comprising:
a filter input for receiving an input current signal and a corresponding filter output for providing a filtered output current signal; and
at least two cascading tunable filter stages interposed between the filter input and the filter output for filtering the input current signal to thereby obtain the filtered output current signal according to a tunable frequency response;
each said tunable filter stage comprising a current mirror circuit having first and second branches configured to generate a stage output current by mirroring a stage input current, and two passive networks, one coupled to an output of the first branch and the other one coupled to an output of the second branch of the current mirror circuit, and each passive network including a tunable element operative to adjust a frequency response of the tunable filter stage responsive to a control signal, and thereby adjust an overall frequency response of the tunable current-mode filter; and
a control input configured to receive the control signal, such that changing a value of the control signal changes the overall frequency response of the tunable current-mode filter.

2. The tunable current-mode filter of claim 1, wherein the tunable current-mode filter comprises a tunable current-mode low pass filter, and wherein each tunable filter stage is configured to have an adjustable cutoff frequency responsive to the control signal, such that the overall cutoff frequency of the tunable current-mode low pass filter is settable via the control signal.

3. The tunable current-mode filter of claim 2, wherein an overall filter order of the tunable current-mode filter is a function of the number of tunable filter stages in cascade connection between the filter input and the filter output.

4. The tunable current-mode filter of claim 2, wherein the tunable element in each passive network comprises a capacitor circuit having a variable capacitance that is set or otherwise adjusted responsive to the control signal.

5. The tunable current-mode filter of claim 1, wherein the tunable element in each passive network comprises a variable reactance circuit operatively associated with the control input, such that changing the value of the control signal changes the reactance of each variable reactance circuit and thereby adjusts an overall frequency response of the tunable current-mode filter.

6. The tunable current-mode filter of claim 5, wherein the variable reactance circuit comprises a switched capacitor circuit, a varactor circuit, or a combined switched capacitor and varactor circuit.

7. The tunable current-mode filter of claim 1, further comprising a calibration circuit included in or otherwise associated with the tunable current-mode filter, wherein the calibration circuit is configured to adjust the control signal based on detecting the overall frequency response of the tunable current-mode filter in comparison with a desired overall frequency response.

8. The tunable current-mode filter of claim 7, wherein the calibration circuit is configured to detect the overall frequency response of the tunable current-mode filter by directly or indirectly detecting an overall delay time of the tunable current-mode filter.

9. The tunable current-mode filter of claim 7, wherein the calibration circuit comprises a tunable replica circuit operating as a surrogate for the tunable current-mode filter, said tunable replica circuit responsive to the control signal in like manner as the tunable current-mode filter, and a control circuit configured to detect the overall frequency response of the tunable current-mode filter indirectly by detecting an overall frequency response of the tunable replica circuit.

10. The tunable current-mode filter of claim 9, wherein the tunable replica circuit is placed in a feed-back loop to form an oscillator circuit having an oscillation frequency dependent on the overall frequency response of the tunable replica circuit, and wherein the calibration circuit is configured to detect the overall frequency response of the tunable current-mode filter by detecting the oscillation frequency of the oscillator circuit.

11. The tunable current-mode filter of claim 7, wherein the calibration circuit comprises a digital processor configured to detect the overall frequency response of the tunable current-mode filter by detecting an oscillation frequency of an oscillator circuit, where the oscillation frequency is dependent on the overall frequency response of the tunable current-mode filter.

12. The tunable current-mode filter of claim 11, further comprising one or more isolation circuits operable by the digital processor and configured to place the tunable current-mode filter during a first time into a calibration mode wherein it operates as part of the oscillator circuit for detection of the overall frequency response of the tunable current-mode filter and corresponding adjustment of the control signal, and to place the tunable current-mode filter during a second time into an operation mode wherein it provides current-mode filtering as part of a signal processing chain.

13. The tunable current-mode filter of claim 1, wherein each passive network in comprises m reactive components, where m is an integer ≧1, and m−1 resistive components, that are operative in conjunction with transistor output impedances in a respective branch of the current mirror circuit to form an m-order low pass filter.

14. The tunable current-mode filter of claim 1, further comprising a DC offset detection circuit configured to generate an offset reduction control signal responsive to detecting DC offset in at least one of the tunable filter stages of the tunable current-mode filter, and further comprising an offset reduction transistor in the at least one of the tunable filter stages, said offset reduction transistor configured to reduce DC offset in the at least one of the tunable filter stages responsive to the offset reduction control signal.

15. A wireless communication transmitter comprising:
a current-mode mixer configured to generate a transmit signal by modulating a carrier frequency signal according to a filtered current-mode information signal;
a tunable current-mode filter configured to generate the filtered current-mode information signal by filtering a current-mode information signal, wherein an overall frequency response of the tunable current-mode filter is tunable responsive to a control signal;
a current-mode digital-to-analog converter (DAC) configured to generate the current-mode information signal from a digital baseband information signal; and
a control circuit configured to adjust the control signal according to a desired frequency response for the tunable current-mode filter;
said tunable current-mode filter comprising:
a filter input for receiving an input current signal and a corresponding filter output for providing a filtered output current signal; and
at least two cascading tunable filter stages interposed between the filter input and the filter output for filtering the input current signal to thereby obtain the filtered output current signal according to a tunable frequency response;
each said tunable filter stage comprising a current mirror circuit having first and second branches configured to generate a stage output current by mirroring a stage input current, and two passive networks, one coupled to an output of the first branch and the other one coupled to an output of the second branch, and each passive network including a tunable element operative to adjust a frequency response of the tunable filter stage responsive to a control signal, and thereby adjust an overall frequency response of the tunable current-mode filter; and
a control input configured to receive the control signal, such that changing a value of the control signal changes the overall frequency response of the tunable current-mode filter.

16. A method of adjusting frequency response in a signal processing chain that includes a tunable current-mode filter having at least two cascaded tunable filter stages and having an overall frequency response adjustable as a function of a control signal applied to the tunable current-mode filter, each tunable filter stage comprising a current mirror circuit having first and second branches and two passive networks, each one coupled to an output of a respective one of the branches and each one including a tunable element responsive to the control signal, the method comprising:
detecting an overall frequency response of the tunable current-mode filter; and
adjusting the control signal as needed according to a desired overall frequency response.

17. The method of claim 16, wherein detecting an overall frequency response of the tunable current-mode filter comprises directly or indirectly detecting an overall delay time of the tunable current-mode filter.

18. The method of claim 16, wherein detecting an overall frequency response of the tunable current-mode filter comprises detecting an overall frequency response of a tunable replica circuit operating as a surrogate for the tunable current-mode filter, said tunable replica circuit responsive to the control signal in like manner as the tunable current-mode filter.

19. The method of claim 18, wherein detecting an overall frequency response of a tunable replica circuit comprises placing the tunable replica circuit in a feedback loop to form an oscillator circuit and detecting an oscillation frequency of the oscillator circuit that depends on the overall frequency response of the tunable replica circuit.

20. The method of claim 16, wherein detecting an overall frequency response of the tunable current-mode filter comprises temporarily placing the tunable current-mode filter into a calibration mode where it operates as part of an oscillator circuit and therein detecting an oscillation frequency that is dependent on the overall frequency response of the tunable current-mode filter and correspondingly adjusting the control signal according to a desired overall frequency response.

21. The method of claim 20, further comprising detecting the overall frequency response of the tunable current-mode filter via a digital signal processor included in the signal processing chain and configured to generate or otherwise control generation of an analog current-mode signal that is filtered by the tunable current-mode filter, at least when the tunable current-mode filter is not operating in the calibration mode.

22. The method of claim 16, further comprising detecting DC offset in at least one of the tunable filter stages and generating a corresponding offset reduction control signal to control an offset reduction transistor included in the tunable filter stage, wherein the offset reduction transistor is configured to reduce DC offset responsive to the offset reduction control signal.
